(19) United States
(12) Patent Application Publication
(10) Pub. No.: US 2008/0280114 A1
(43) Pub. Date: Nov. 13, 2008

(54) METHOD FOR DEPOSITING A TARGET MATERIAL ONTO A SUBSTRATE, LASER DEPOSITION SYSTEM FOR PERFORMING THE METHOD, AND HOUSING MADE BY THE METHOD

(75) Inventors: JIE TANG, Shenzhen (CN); WU-BING LI, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: SHENZHEN FUTAIHONG PRECISION INDUSTRY CO., LTD., ShenZhen City (CN); Sutech Trading Limited, Tortola (VG)

(21) Appl. No.: 11/946,301

(22) Filed: Nov. 28, 2007

(30) Foreign Application Priority Data
May 9, 2007 (CN) 200710074325.4

(51) Int. Cl. B32B 3/30; C23C 14/54

(52) U.S. Cl. 428/210; 118/620; 118/697; 427/596; 428/195.1

(57) ABSTRACT

A laser deposition system (10) for depositing a target material onto a substrate includes a target (12), a laser emitter (13), and a substrate (20). The laser emitter is configured to emit a laser beam (130). The target has a first surface (121), with the laser beam shining onto the first surface. The laser beam generates a vaporized target material (120) from the first surface of the target. The substrate is disposed between the laser emitter and the target so that the laser beam first transmits through the substrate and then projects onto the first surface of the target. The vaporized target material is cooled and deposited on the substrate. A method for depositing a target material onto a substrate and a housing are also provided.

### BACKGROUND OF THE INVENTION

1. Field of the Invention

The present invention generally relates to methods for depositing a target material onto a substrate, and more particularly, to a method for depositing metal onto a substrate by laser deposition, to a laser deposition system for performing the method, and to a housing made by the method.

2. Description of Related Art

Typically, processes for depositing inorganic material or metal onto an article can be performed by vacuum deposition processes, for example, physical vapor deposition, magnetron sputtering deposition, chemical vapor deposition, and so on. The vacuum deposition processes is suitable to form large area coatings on an exposed portion of an article. However, the vacuum deposition processes is not suitable to deposit material to form a predetermined pattern.

In order to forming a predetermined pattern on a surface of an article by the vacuum deposition processes, a printing process is necessary to be employed to assist the formation of the predetermined pattern. During the formation process of the predetermined pattern, a decorative coating is firstly formed onto the surface of the article by any one of the vacuum deposition processes. Secondly, an ink coating is applied onto the decorative coating to form a predetermined pattern using the printing process. Thirdly, the article is immersed into an etching solution to remove a portion of the decorative coating, which is not covered by the ink coating. Finally, the ink coating is removed from the decorative coating by using an organic solution. Thus, the predetermined pattern is remained on the surface of the article, as the decorative coating is partially removed according to the predetermined pattern. However, the vacuum deposition process with the assistance of the printing process cannot achieve a desired precision of the predetermined pattern. Further, as many complex processes are employed, the printing process results in increase of the cost of forming the predetermined pattern and is time consuming.

Therefore, an improved method for depositing a target material onto a substrate is desired in order to overcome the above-described shortcomings.

### SUMMARY OF THE INVENTION

In one embodiment thereof, a laser deposition system for depositing a target material onto a substrate is provided. The laser deposition system includes a laser emitter, a target, and a substrate. The laser emitter is configured to emit a laser beam. The target has a first surface, with the laser beam shining onto the first surface. The laser beam generates a vaporized target material from the first surface of the target. The substrate is disposed between the laser emitter and the target so that the laser beam can transmit through the substrate and project onto the first surface of the target. The vaporized target material is cooled and deposited on the substrate.

Other advantages and novel features will become more apparent from the following detailed description of preferred embodiments when taken in conjunction with the accompanying drawings.

### BRIEF DESCRIPTION OF THE DRAWINGS

Many aspects of the method for depositing a target material onto a substrate can be better understood with reference to the following drawing. The components in the drawing are not necessarily drawn to scale, the emphasis instead being placed upon clearly illustrating the principles of the method for depositing a target material onto a substrate. Moreover, in the drawing like reference numerals designate corresponding parts throughout the several views.

FIG. 1 a schematic view of a preferred embodiment of a housing with a predetermined ornamental pattern formed thereon;

FIG. 2 is a cross-sectional view taken along line II-II of FIG. 1, showing the housing; and

FIG. 3 is a schematic view of a preferred embodiment of a laser deposition system.

### DETAILED DESCRIPTION OF THE INVENTION

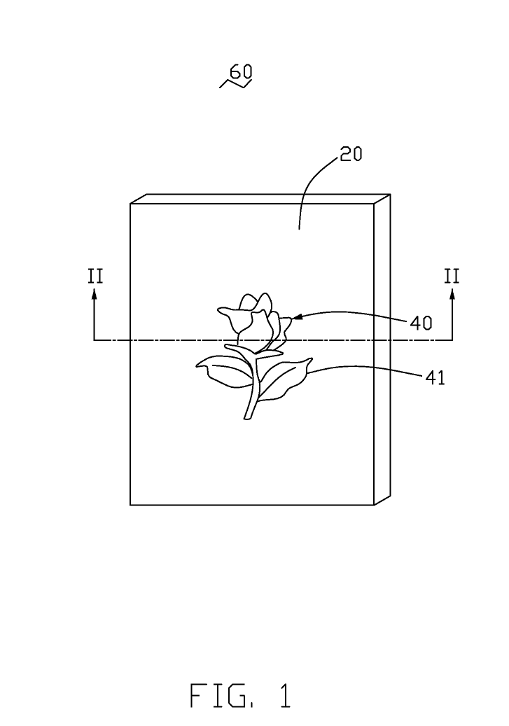

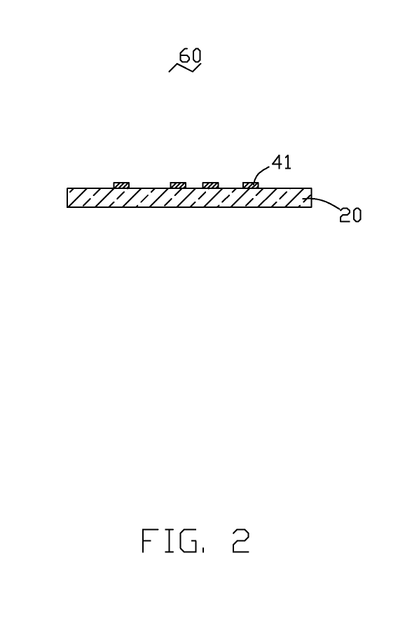

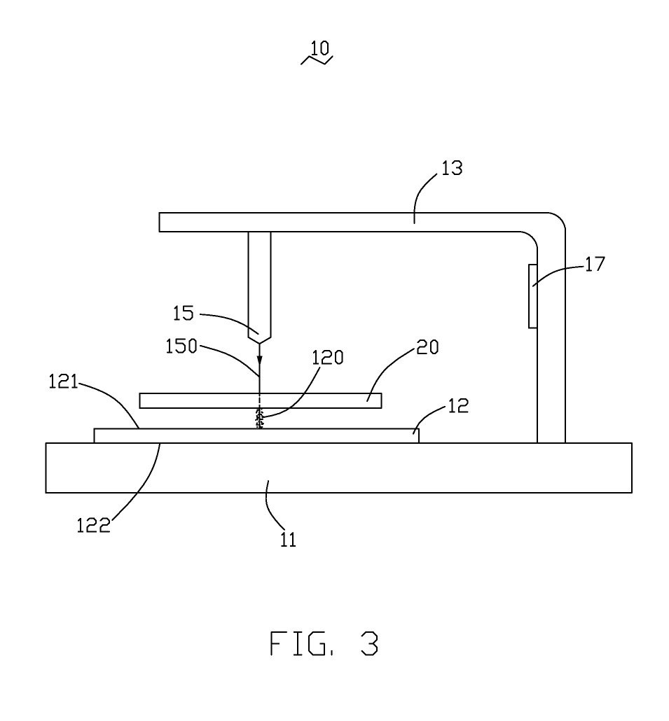

Referring to FIG. 1, FIG. 2, and FIG. 3, in a present embodiment, a housing 60 and a laser deposition system 10 are provided. The housing 60 includes a substrate 20 and an ornamental pattern 40 formed on a first surface of the substrate 20. The pattern 40 is defined by a plurality of lines. The plurality of lines is formed by a line-alike metal coating 41. The laser deposition system 10 for depositing a target material onto a substrate 20 includes a work base 11, a target 12, a servo manipulator 13, a laser emitter 15, and a control system 17.

The target 12 has a first surface 121 and a second surface 122 on the opposite side of the first surface 121. The target 12 is disposed on the work base 11, with the second surface 122 attached to the work base 11. The first surface 121 of the target 12 is shaped similar to that of the substrate 20, which is prearranged to receive the target material. The target 12 may be made of a metal selected from the group consisting of copper, aluminum, titanium, steel, silver, chromium, tin, and alloys thereof.

The servo manipulator 13 is movably disposed above the target 11 and configured to hold the laser emitter 15. The laser emitter 15 is mounted on the servo manipulator 13 and configured to emit a laser beam 150 vertically incident upon the first surface 121 of the target 12. The control system 17 is a programmable control system, which is electronically connected to the servo manipulator 13 and configured to drive the servo manipulator 13 to move along a predetermined path. The control system 17 may be further configured to record information of the ornamental pattern 40 (referring to FIG. 1) on the substrate 20. The control system 17 transforms the information of the ornamental pattern 40 into a controlling signal for driving the servo manipulator 13 with the laser emitter 15 to move along the lines of the ornamental pattern 40.

The substrate 20 is made of a partially transparent material such as glass or polycarbonate resin thin film. The substrate 20 is disposed between the target 12 and the laser emitter 15, with a surface of the substrate 20 facing the target 12. The substrate 20 can be in close proximity to or in contact with the first surface 121 of the target 12. A distance between the first surface 121 of the target 12 and the substrate 20 is less than 500 microns. The laser beam 150 first penetrates through the substrate 20 and then projects on the first surface 121 of the target 12.

An exemplary method for depositing the target material onto the substrate 20 is provided.

Firstly, the laser deposition system 10 is provided. The laser deposition system 10 is actuated. The substrate 20 is then disposed between the target 12 and the laser emitter 15. The substrate 20 can be in close proximity to or in contact with the first surface 121 of the target 12, with a distance less than 500 microns between the first surface 121 of the target 12 and the substrate 20.

The laser emitter 15 is actuated to emit the laser beam 150 penetrating through the substrate 20 and shining on the first surface 121 of the target 12. As the laser beam 150 projects on the first surface 121 of the target 12, the heat of the laser beam 50 partially melts the projected portion of the target 12. Thus, a target material 120 is vaporized and ejected from the projected portion of the first surface 121 of the target 12. The vaporized target material 120 is then cooled and deposited onto a surface of the substrate 20, which is close to the target 12. The gap between the target 12 and the substrate 20 is narrow to prevent the vaporized target material 120 from developing into a plume. A fine deposited spot on the surface of the substrate 20 can be obtained, with a diameter of the deposited spot substantially varying according to the diameter of the laser beam 150.

The control system 17 is actuated for driving the servo manipulator 13 and the laser emitter 15 to move according to the controlling signal generated from the information of the ornamental pattern 40. Thus, the laser beam 150 is moved to form the lines of the ornamental pattern 40 according to the controlling signal. Accordingly, as the vaporized target material is deposited onto the surface of the substrate 20 during the movement of the laser beam 150, the deposited spot on the substrate 20 is also moved to form the lines of the ornamental pattern 40. As such, the metal coating 41 is formed to define the lines of the ornamental pattern 40, with a width of each of the lines varying according to the diameter of the laser beam 150.

During the exemplary method for depositing the target material onto the substrate 20, it is not necessary to perform the method in a vacuum or in an electrical field. The target 12 can be repeatedly used in the exemplary method, which reduces the consumption of the target material.

It should be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A laser deposition system for depositing a target material onto a substrate, comprising:
a laser emitter configured to emit a laser beam;
a target having a first surface, with the laser beam projecting onto the first surface thereby generating a vaporized target material from the first surface of the target; and
a substrate disposed between the laser emitter and the target so that the laser beam first transmits through the substrate and then projects onto the first surface of the target, the vaporized target material being cooled and deposited on the substrate.

2. The laser deposition system as claimed in claim 1, further comprising a work base, the target further comprising a second surface opposite to the first surface, the second surface being attached to the work base.

3. The laser deposition system as claimed in claim 1, wherein the target is made of a metal selected from the group consisting of copper, aluminum, titanium, steel, silver, chromium, tin, and alloys thereof.

4. The laser deposition system as claimed in claim 1, further comprising a servo manipulator and a programmable control system, the laser emitter being mounted on the servo manipulator, the programmable control system being configured to record information of a predetermined ornamental pattern and transform the information of the ornamental pattern into a controlling signal for driving the laser emitter so that the laser beam moves along a path defined by the ornamental pattern.

5. The laser deposition system as claimed in claim 1, wherein the substrate is made of a material at least partially transparent to the laser beam.

6. The laser deposition system as claimed in claim 1, wherein the substrate is made of glass or polycarbonate resin thin film.

7. The laser deposition system as claimed in claim 1, wherein a distance between the target and the substrate is less than 500 microns.

8. A method for depositing a target material onto a substrate, comprising the steps of:
providing a laser emitter, a substrate, and a target comprising a target material, the substrate being disposed between the laser emitter and the target;
actuating the laser emitter to emit a laser beam, with the laser beam transmitting through the substrate and projecting onto a first surface of the target;
vaporizing a portion of the target material from the projected portion of the first surface of the target by the laser beam; and
depositing the vaporized portion of the target material onto the substrate.

9. The method as claimed in claim 8, wherein the target is made of a metal selected from the group consisting of copper, aluminum, titanium, steel, silver, chromium, tin, and alloys thereof.

10. The method as claimed in claim 8, further comprising a step of providing a servo manipulator and a programmable control system, the laser emitter being mounted on the servo manipulator, the programmable control system being configured to record information of a predetermined ornamental pattern and transform the information of the ornamental pattern into a controlling signal for driving the servo manipulator.

11. The method as claimed in claim 10, further comprising a step of actuating the controlling system to drive the laser emitter to move along a path defined by the ornamental pattern.

12. The method as claimed in claim 8, wherein the substrate is made of a material at least partially transparent to the laser beam.

13. The method as claimed in claim 8, wherein the substrate is made of glass or polycarbonate resin thin film.

14. The method as claimed in claim 8, wherein a distance between the target and the substrate is less than 500 microns.

15. A housing, comprising:
a transparent substrate; and
a pattern formed on a surface of the transparent substrate, the pattern being defined by a plurality of lines, each of the lines being formed by a line-alike metal coating formed thereon.

16. The housing as claimed in claim 15, wherein the line-alike metal coating is formed via a moveable laser beam projecting onto a metal target disposed in close to the transparent substrate, the laser beam being moved along the lines of the pattern, the projected portion of the target being partially melted and deposited onto the lines of the pattern.

17. The housing as claimed in claim 15, wherein a width of each of the lines varies with a diameter of the laser beam.

18. The housing as claimed in claim 15, wherein the transparent substrate is made of glass or polycarbonate resin thin film.
